(19) United States
(12) Patent Application Publication
(10) Pub. No.: US 2026/0125818 A1
(43) Pub. Date: May 7, 2026

(54) HORIZONTAL ELECTROPLATING PRODUCTION LINE

(71) Applicant: UNIVERSAL CIRCUIT BOARD EQUIPMENT CO., LTD., Dongguan (CN)

(72) Inventor: Takwo CHAN, Dongguan (CN)

(73) Assignee: UNIVERSAL CIRCUIT BOARD EQUIPMENT CO., LTD., Dongguan (CN)

(21) Appl. No.: 19/055,841

(22) Filed: Feb. 18, 2025

(30) Foreign Application Priority Data
Nov. 4, 2024 (CN) 202411560895.4

(51) Int. Cl. C25D 17/04; C25D 5/08; C25D 17/20; C25D 17/28; C25D 21/12

(52) U.S. Cl. CPC C25D 17/04; C25D 5/08; C25D 17/20; C25D 17/28; C25D 21/12

(57) ABSTRACT

A horizontal electroplating production line includes a horizontal electroplating apparatus and a circuit board feeding device. The horizontal electroplating apparatus includes a first frame, an electroplating tank and a horizontal electroplating conveying device arranged at the first frame, the electroplating tank extends along a first direction, the horizontal electroplating conveying device is configured to clamp a circuit board and move the circuit board in the electroplating tank for electroplating, the circuit board feeding device includes a second frame and a feeding conveying mechanism arranged at the second frame, the feeding conveying mechanism is a conveying line with a certain length, and the feeding conveying mechanism is configured to place the circuit board horizontally and convey the circuit board to the horizontal electroplating conveying device of the electroplating apparatus.

### CROSS-REFERENCE TO RELATED APPLICATIONS

This application claims priority to Chinese Patent Application No. 202411560895.4, filed on Nov. 4, 2024, the entire contents of which are incorporated herein by reference.

### TECHNICAL FIELD

The present application relates to the technical field of circuit board electroplating, and in particular to a horizontal electroplating production line.

### BACKGROUND

Conventional circuit board electroplating, whether using a gantry line or a vertical continuous electroplating (VCP), employs a vertical electroplating method. In this process, the circuit board is clamped vertically by a fixture and submerged in a chemical. A device with a vibrating function is used to agitate the circuit board, allowing the chemical to flow through the interconnection holes of the circuit board, and electroplating is formed under the conductive effect of the chemical. Electroplating equipment of this type requires a large footprint, with loading and unloading operations performed by robotic arms. The manufacturing cost is high, and the precision of the electroplating is relatively low, which cannot meet the requirements for high-precision electroplating.

### SUMMARY

The main objective of the present application is to provide a horizontal electroplating production line, which aims to solve the problems of high manufacturing cost and poor electroplating accuracy in conventional electroplating apparatus.

In order to achieve the above objective, the present application provides a horizontal electroplating production line, including:
a horizontal electroplating apparatus including a first frame, an electroplating tank and a horizontal electroplating conveying device arranged at the first frame, wherein two ends of the electroplating tank are respectively provided with an inlet and an outlet, and the horizontal electroplating conveying device is configured to drive a circuit board to move from the inlet into the electroplating tank towards the outlet; and
a circuit board feeding device arranged at one end of the electroplating tank close to the inlet, wherein the circuit board feeding device includes a second frame and a feeding conveying mechanism arranged at the second frame, the feeding conveying mechanism is configured to place the circuit board horizontally and convey the circuit board along a first direction, so that the circuit board entering the electroplating tank remains horizontal and moves to the horizontal electroplating conveying device.

In an embodiment, the circuit board feeding device further includes a first positioning mechanism and a first material pushing mechanism, the first positioning mechanism is configured to position the circuit board on the feeding conveying mechanism to a preset position, the first material pushing mechanism is configured to drive the circuit board on the feeding conveying mechanism to move in the first direction, so that adjusting a spacing between two adjacent circuit boards that are positioned by the first positioning mechanism and are arranged along the first direction.

In an embodiment, the first material pushing mechanism is configured to push the circuit board positioned by the first positioning mechanism to move in the first direction, so that a spacing between the pushed circuit board and the previous circuit board positioned by the first positioning mechanism is a preset value L, and an actual spacing between the two circuit boards is D, where L−1.5 mm≤D≤L+1.5 mm.

In an embodiment, the horizontal electroplating production line includes a flipping device and two horizontal electroplating apparatuses, the flipping device is arranged between the two horizontal electroplating apparatuses to flip and convey the circuit board that has been electroplated in one of the horizontal electroplating apparatuses to the other horizontal electroplating apparatus, so that the horizontal electroplating conveying device of the two horizontal electroplating apparatus respectively grip opposite sides of the circuit board.

In an embodiment, the flipping device includes a third frame, a feeding mechanism and a flipping mechanism arranged at the third frame, the feeding mechanism is configured to place the circuit board horizontally, and the flipping mechanism is configured to flip the circuit board on the feeding mechanism.

In an embodiment, the flipping mechanism includes a driving assembly, a rotating shaft and a clamping assembly, the clamping assembly is arranged at the rotating shaft, the rotating shaft is drivingly connected to the driving assembly, the clamping assembly is provided with a slot for inserting the circuit board, and the driving assembly is configured to drive the rotating shaft to rotate, so that the clamping assembly drives the circuit board to flip.

In an embodiment, the feeding mechanism includes a first conveying line, a second conveying line, a third conveying line and a fourth conveying line, the first conveying line and the second conveying line transport the circuit board in the first direction, the flipping mechanism is arranged between the first conveying line and the second conveying line to flip the circuit board on the first conveying line to the second conveying line, the fourth conveying line extends along a conveying direction of the first conveying line, the third conveying line is arranged along the second direction to transport the circuit board on the second conveying line to the fourth conveying line, and the first direction and the second direction forms an angle.

In an embodiment, the flipping device further includes a second material pushing mechanism and a second positioning mechanism, the second positioning mechanism is arranged at the fourth conveying line to position the circuit board to a preset position, the second material pushing mechanism is configured to push the circuit board along the first conveying line, the second conveying line, the third conveying line and the fourth conveying line in sequence, push the circuit board positioned by the second positioning mechanism to the horizontal electroplating apparatus, and adjust the spacing between two adjacent circuit boards positioned by the second positioning mechanism and arranged along the first direction.

In an embodiment, the horizontal electroplating conveying device further includes a clamping mechanism and an electroplating conveying mechanism, a rail is arranged at the first frame in a horizontal direction, the clamping mechanism includes a sliding member and a clamping member connected to each other, the clamping member is arranged at the electroplating conveying mechanism to clamp the circuit board, the sliding member is slidably connected to the rail, and the electroplating conveying mechanism is configured to drive the clamping mechanism to move along the rail to convey the circuit board.

In an embodiment, the clamping member includes:
a fixing clamp;
a movable clamp movably mounted at the fixing clamp through a connecting assembly, the movable clamp is configured to cooperate with the fixing clamp to clamp the circuit board; and
a lifting support wheel arranged at a side of the movable clamp away from the fixing clamp, when the clamping mechanism moves through the electroplating conveying mechanism, the lifting support wheel ascends or descends to open or close the movable clamp and the fixing clamp.

In an embodiment, the horizontal electroplating conveying device further includes a guide assembly arranged at the first frame, the guide assembly includes a first guide member and a second guide member, the first guide member is located at a path of the clamping mechanism for loading, the second guide member is located at a path of the clamping mechanism for unloading, and both the first guide member and the second guide member have a guide slope;
on the path of the clamping mechanism for loading, when the guide slope is configured to guide the movement of the clamping mechanism and abut against the lifting support wheel, a spacing between the fixing clamp and the movable clamp is increased, in order to allow the circuit board to be clamped; and
on the path of the clamping mechanism for unloading, when the guide slope is configured to guide the movement of the clamping mechanism and abut against the lifting support wheel, the spacing between the fixing clamp and the movable clamp is increased, in order to allow the circuit board to be released

In an embodiment, the electroplating conveying mechanism includes:
a conveying steel belt slidably arranged at the first frame, wherein the clamping mechanism is arranged at the conveying steel belt;
a driving mechanism including a conveying driving wheel and a conveying driven wheel, the conveying driving wheel and the conveying driven wheel are respectively arranged at two ends of the first frame, and the conveying driving wheel and the conveying driven wheel are connected through the conveying steel belt to form a closed-loop transmission to achieve continuous conveying; and
a tensioning mechanism elastically connected to the conveying steel belt and the first frame, when the conveying steel belt slides on the first frame, the tensioning mechanism undergoes elastic deformation to change a horizontal spacing between the first frame and the conveying steel belt to tension the conveying steel belt.

In an embodiment, the horizontal electroplating apparatus further includes a cathode conductive clamp reverse stripping device including a deplating tank and a stripping assembly, the deplating tank is arranged at the first frame, the conveying steel belt is configured to convey the clamping mechanism into the deplating tank, so that the clamping mechanism and the stripping assembly form a conductive loop to strip an electroplating material on the clamping mechanism.

In an embodiment, the horizontal electroplating apparatus further includes a conductive device including:
a conductive oil groove assembly provided with a conductive oil;
a cathode assembly connected with an anode of a power supply to generate a current;
a conductive slider assembly configured in the clamping mechanism, wherein the conductive slider assembly is arranged in the conductive oil groove assembly and submerged in the conductive oil, the conductive slider assembly is electrically connected to the cathode assembly to transmit the current to the horizontal electroplating fixture, so that the circuit board on the horizontal electroplating fixture is charged; and
a re-circulating mechanism including an oil collecting groove and a re-circulating assembly, the oil collecting groove is configured to store the conductive oil, the conductive oil groove assembly is connected to the oil collecting groove through the re-circulating assembly to form a circulation path, allowing the conductive oil in the oil collecting groove to circulate with the conductive oil in the conductive oil groove assembly.

In an embodiment, the conductive device further includes an oil supply mechanism, the re-circulating mechanism further includes an overflow assembly, the oil supply mechanism is connected to the conductive oil groove assembly to provide the conductive oil to the conductive oil groove assembly, the overflow assembly has an overflow port, the overflow assembly is connected to the conductive oil groove assembly through the overflow port, the conductive oil groove assembly is connected to the oil collecting groove through the overflow assembly, the conductive oil groove assembly has a preset volume, when an liquid volume in the conductive oil groove assembly exceeds the preset volume, the conductive oil in the conductive oil groove assembly flows into the oil collecting groove through the overflow assembly.

In an embodiment, the horizontal electroplating apparatus further includes an anode spray device arranged in the electroplating tank, the anode spray device includes:
an anode mesh well plate;
an anode mesh detachably mounted at the anode mesh well plate;
a spray assembly mounted at a side of the anode mesh away from the anode mesh well plate; and
a conductive assembly, the anode mesh is connected to a rectifier through the conductive assembly.

In an embodiment, at least two sets of the anode spray devices are mounted at intervals in the electroplating tank, spray sides of the two sets of the anode spray devices are arranged oppositely, and an electroplating cavity for accommodating the circuit board for electroplating is formed between any two sets of the anode spray devices arranged oppositely.

In an embodiment, the anode mesh well plate includes:
a well plate body provided with a plurality of meshes and a plurality of first spray holes, wherein each of the meshes is arranged in a hexagonal shape, the meshes are arranged in a honeycomb array at the well plate body, a plurality of first spray holes are arranged at intervals at the well plate body, and the well plate body has a spray side facing the circuit board and spraying the circuit board; and
a guide wheel mounted at the spray side of the well plate body and configured to abut against the circuit board.

In an embodiment, the horizontal electroplating production line further includes:
a copper dissolving device including:
a copper dissolving tank provided with a divider plate, wherein the divider plate divides the copper dissolving tank into a first tank body and a second tank body, the first tank body has a liquid inlet for a reaction solution to enter, and a copper particle basket for placing a pure copper; an upper portion of the divider plate has an overflow portion that connects the first tank body with the second tank body; the second tank body is provided with an overflow port for an outflow of the electroplating solution;
a conveying pipeline connecting the second tank body with the first tank body, so that the first tank body, the overflow portion, the second tank body and the conveying pipeline are connected to form an internal circulation loop; and
an overflow mechanism mounted at the overflow port and configured to convey the liquid in the second tank body to the electroplating tank.

In an embodiment, the horizontal electroplating production line further includes:
a board washing device arranged at an entrance of the electroplating tank and located between the circuit board feeding device and the electroplating tank, and/or the board washing device arranged at an exit of the electroplating tank; and
a board drying device arranged at the exit of the electroplating tank and located at a side of the board washing device away from the electroplating tank, so as to remove water from the circuit board after electroplating and cleaning by the board washing device.

In technical solutions of the present application, by adopting a circuit board feeding device in the horizontal electroplating production line to cooperate with horizontal electroplating apparatus for electroplating, thereby reducing the manufacturing cost of the apparatus. Specifically, the horizontal electroplating production line includes a horizontal electroplating apparatus and a circuit board feeding device. The horizontal electroplating equipment includes a first frame, an electroplating tank and a horizontal electroplating conveying device arranged at the first frame. The electroplating tank extends along a first direction, and the horizontal electroplating conveying device is configured to champ and move the circuit board in the electroplating tank for electroplating. The circuit board feeding device includes a second frame and a feeding conveying mechanism mounted at the second frame. The feeding conveying mechanism is a conveying line with a certain length that forms a first horizontal conveying surface, thereby placing the circuit board horizontally. The feeding conveying mechanism conveys the circuit board in a horizontal direction to the horizontal electroplating conveying device of the electroplating equipment. It can be understood that during the entire conveying process, the circuit board remains in a horizontal orientation and does not need to be operated by robotic arms. Therefore, the equipment of this production line occupies less space and has lower manufacturing costs than traditional electroplating apparatus. The horizontal board movement may meet high-precision electroplating requirements and has higher product quality.

### BRIEF DESCRIPTION OF THE DRAWINGS

In order to illustrate the technical solutions in the embodiments of the present application or in the related art more clearly, the following briefly introduces the accompanying drawings required for the description of the embodiments or the related art. Obviously, the drawings in the following description are only part of embodiments of the present application. For those skilled in the art, other drawings can also be obtained according to the structures shown in these drawings without any creative effort.

FIG. 1 is a schematic structural diagram of a horizontal electroplating production line according to an embodiment of the present application.

FIG. 2 is a top view of a horizontal electroplating production line according to an embodiment of the present application.

FIG. 3 is a schematic structure diagram of a connection of a circuit board feeding device and a horizontal electroplating apparatus of a horizontal electroplating production line according to an embodiment of the present application.

FIG. 4 is a schematic structural diagram of a circuit board feeding device of a horizontal electroplating production line according to an embodiment of the present application.

FIG. 5 is a schematic partial structural diagram of a circuit board feeding device of a horizontal electroplating production line according to an embodiment of the present application.

FIG. 6 is a schematic structure diagram of a connection of a flipping device and two horizontal electroplating apparatus of a horizontal electroplating production line according to an embodiment of the present application.

FIG. 7 is a schematic structure diagram of a flipping device of a horizontal electroplating production line according to an embodiment of the present application.

FIG. 8 is a schematic partial structure diagram of a flipping device of a horizontal electroplating production line according to an embodiment of the present application.

FIG. 9 is a schematic diagram of a conveying route of a circuit board by a flipping device of a horizontal electroplating production line according to an embodiment of the present application.

FIG. 10 is a schematic structure diagram of a flipping mechanism of a flipping device of a horizontal electroplating production line according to an embodiment of the present application.

FIG. 11 is a schematic diagram of an internal structure of a horizontal electroplating apparatus of a horizontal electroplating production line according to an embodiment of the present application.

FIG. 12 is a schematic structure diagram of a horizontal electroplating conveying device of a horizontal electroplating production line according to an embodiment of the present application.

FIG. 13 is a schematic structure diagram of a clamping mechanism and a conveying steel belt in a horizontal electroplating conveying device of a horizontal electroplating production line according to an embodiment of the present application.

FIG. 14 is a schematic structure diagram of a clamping mechanism and a conveying steel belt of a horizontal electroplating production line according to an embodiment of the present application.

FIG. 15 is a schematic diagram of an assembly structure of a clamping mechanism and a rail of a horizontal electroplating production line according to an embodiment of the present application.

FIG. 16 is a schematic diagram of mating structure of a clamping member and a guide assembly of a horizontal electroplating production line according to an embodiment of the present application.

FIG. 17 is a schematic structure diagram of an electroplating conveying mechanism of a horizontal electroplating production line according to an embodiment of the present application.

FIG. 18 is a schematic structure diagram of a conveying steel belt, a conveying driving wheel, and a conveying driven wheel of a horizontal electroplating production line according to an embodiment of the present application.

FIG. 19 is a schematic structure diagram of a clamping member, a deplating tank and a cathode conductive clamp reverse stripping device of a horizontal electroplating production line according to an embodiment of the present application.

FIG. 20 is a schematic structure diagram of a conductive device of a horizontal electroplating production line according to an embodiment of the present application.

FIG. 21 is a schematic enlarged view of the area A in FIG. 20.

FIG. 22 is a schematic structure diagram of a clamping mechanism, a circuit board and an anode spray device of a horizontal electroplating production line according to an embodiment of the present application.

FIG. 23 is a schematic structure diagram of an anode spray device of a horizontal electroplating production line according to an embodiment of the present application.

FIG. 24 is a schematic diagram of a bottom structure of an anode spray device of a horizontal electroplating production line according to an embodiment of the present application.

FIG. 25 is a schematic structure diagram of an anode mesh well plate of a horizontal electroplating production line according to an embodiment of the present application.

FIG. 26 is a schematic structure diagram of a copper dissolving device of a horizontal electroplating production line according to an embodiment of the present application.

FIG. 27 is a lateral sectional view of a copper dissolving device of a horizontal electroplating production line according to an embodiment of the present application.

The realization of the objective, functional characteristics, and advantages of the present application are further described with reference to the accompanying drawings.

### DETAILED DESCRIPTION OF THE EMBODIMENTS

The technical solutions of the embodiments of the present application will be described in more detail below with reference to the accompanying drawings. It is obvious that the embodiments to be described are only some rather than all of the embodiments of the present application. All other embodiments obtained by those skilled in the art based on the embodiments of the present application without creative efforts shall descend within the scope of the present application.

It should be noted that if there are directional indications, such as up, down, left, right, front, back, etc., involved in the embodiments of the present application, the directional indications are only configured to explain a certain posture as shown in the accompanying drawings. If the specific posture changes, the directional indication also changes accordingly.

In addition, if there are descriptions related to “first”, “second”, etc. in the embodiments of the present application, the descriptions of “first”, “second”, etc. are only for the purpose of description, and should not be construed as indicating or implying relative importance or implicitly indicates the number of technical features indicated. Thus, a feature delimited with “first”, “second” may expressly or implicitly include at least one of that feature. Besides, the meaning of “and/or” appearing in the application includes three parallel scenarios. For example, “A and/or B” includes only A, or only B, or both A and B. In addition, the technical solutions between the various embodiments can be combined with each other, but must be based on the realization by those skilled in the art. When the combination of technical solutions is contradictory or cannot be realized, it should be considered that the combination of such technical solutions does not exist or descend within the scope of protection claimed in the present application.

Conventional circuit board electroplating, whether using a gantry line or a vertical continuous electroplating (VCP), employs a vertical electroplating method. In this process, the circuit board is clamped vertically by a fixture and submerged in a chemical. A device with a vibrating function is used to agitate the circuit board, allowing the chemical to flow through the interconnection holes of the circuit board, and electroplating is formed under the conductive effect of the chemical. Electroplating equipment of this type requires a large footprint, with loading and unloading operations performed by robotic arms. The manufacturing cost is high, and the precision of the electroplating is relatively low, which cannot meet the requirements for high-precision electroplating.

The present application provides a horizontal electroplating production line.

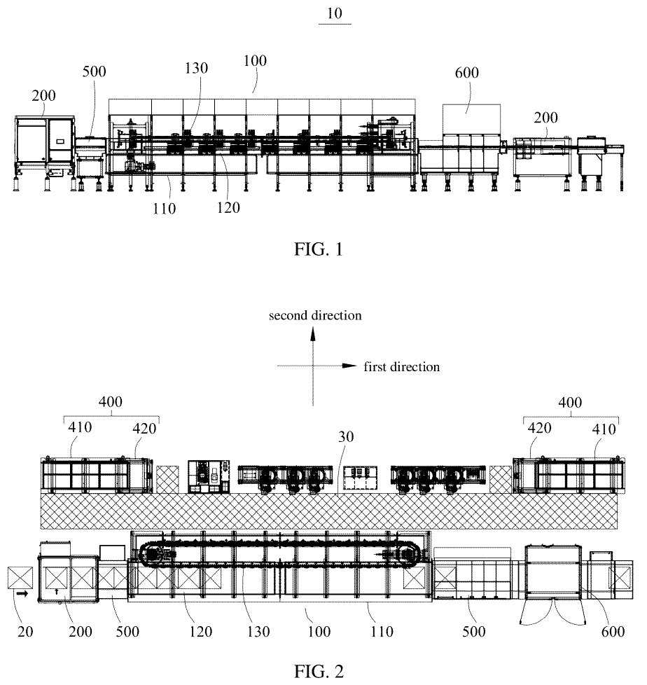

Referring to FIG. 1 to FIG. 5, in one embodiment of the present application, the horizontal electroplating production line includes a horizontal electroplating apparatus 100 and a circuit board feeding device 200. The horizontal electroplating apparatus 100 includes a first frame 110, an electroplating tank 120 and a horizontal electroplating conveying device 130 are arranged at the first frame 110. The electroplating tank 120 extends along a first direction and contains a chemical liquid for electroplating. The horizontal electroplating conveying device 130 is configured to clamp a circuit board 20 to move in the electroplating tank 120 for electroplating. The circuit board feeding device 200 includes a second frame 210 and a feeding conveying mechanism 220 arranged at the second frame 210, the feeding conveying mechanism 220 is a conveying line with a certain length and forms a first horizontal conveying surface, thereby horizontally placing the circuit board 20. The feeding conveying mechanism 220 conveys the circuit board 20 in a horizontal direction to the horizontal electroplating conveying device 130 of an electroplating apparatus. It can be understood that during the entire conveying process, the circuit board 20 maintains a horizontal orientation and does not need to be operated by robotic arms. Therefore, the equipment of this production line occupies less space and has lower manufacturing costs than traditional electroplating apparatus. The horizontal board movement may meet high-precision electroplating requirements and has higher product quality.

It should be noted that the feeding conveying mechanism 220 includes a plurality of rollers 221. Specifically, the plurality of rollers 221 are arranged side by side along the first direction on the second frame 210 to form a conveying line. A plurality of friction wheels 222 are arranged at each of the rollers 221 to form a first horizontal conveying surface. A driving motor is also arranged at the frame. A meshing gear is arranged at the ends of any two adjacent rollers 221. The driving motor drives the plurality of rollers 221 to rotate at the same speed through the gear. The friction wheel 222 is in contact with a bottom of a board surface to drive the circuit board 20 to move. The contact position of the friction wheel 222 with the circuit board 20 may be configured with a structure such as soft rubber to prevent scratching.

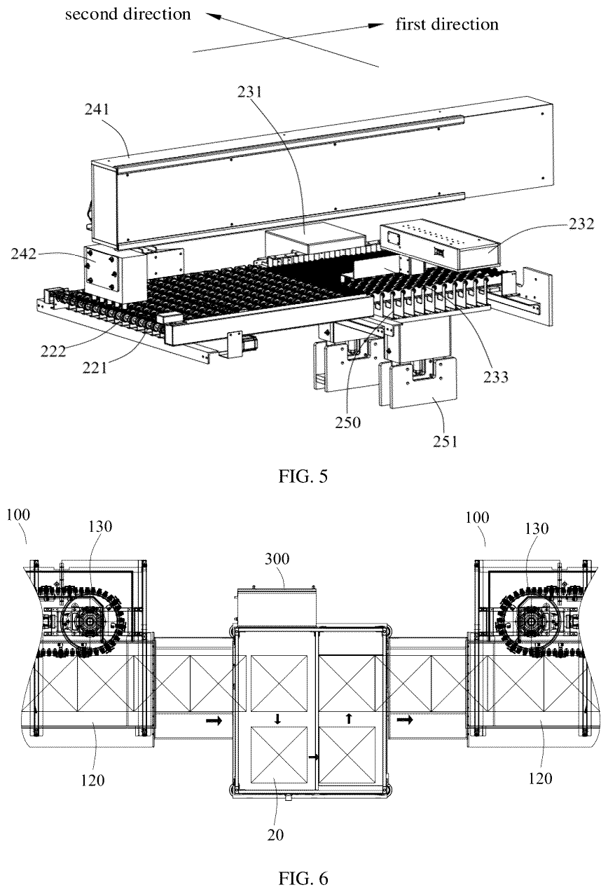

In an embodiment, as shown in FIG. 4 to FIG. 5, the circuit board feeding device 200 also includes a first positioning mechanism 230, a first material pushing mechanism 240 arranged at the second frame 210. The first positioning mechanism 230 is configured to position the circuit board 20 on the feeding conveying mechanism 220 to a preset position, so that an edge of the circuit board 20 is aligned with the horizontal electroplating conveying device 130, the circuit board 20 after positioning moves in the first direction into the electroplating tank 120. The first material pushing mechanism 240 includes a set of first linear motors 241 and first material pushing members 242 arranged along the first direction. The first material pushing member 242 is drivably connected to the first linear motor 241. The first linear motor 241 is configured to drive the first material pushing member 242 to move back and forth in the first direction and drive the circuit board 20 to move. The first positioning mechanism 230 includes a second linear motor 232 and a second material pushing member 233 arranged along a second direction. The feeding conveying mechanism 220 is also provided with a first positioning baffle 231. The second linear motor 232 drives the second material pushing member 233 to push the circuit board 20 to the first positioning baffle 231 for positioning. During production and loading, the operator generally puts a plurality of circuit boards 20 on the feeding conveying mechanism 220 in sequence. The first material pushing mechanism 240 is configured to adjust a spacing between two adjacent circuit boards 20 that are positioned by the first positioning mechanism 230 and are arranged along the first direction.

During positioning, the first positioning mechanism 230 may laterally push the circuit board 20, which could cause the friction wheel 222 to scrape against a surface of the circuit board 20. Therefore, a transfer track 250 may be arranged along the second direction below the feeding conveying mechanism 220, a plurality of driven wheels are arranged at intervals along the second direction on an upper end of the transfer track 250, and a first lifting mechanism 251 is arranged at a lower end of the transfer track 250 for lifting. When the circuit board 20 reaches a positioning position, the first lifting mechanism 251 drives the transfer track 250 to ascend and lift the circuit board 20. The first positioning mechanism 230 pushes the circuit board 20 to move in the second direction, the surface of the circuit board 20 slides and abuts against the driven wheel to avoid scratches. When the positioning is completed, the first lifting mechanism 251 drives the transfer track 250 to descend and puts the circuit board 20 back to a first conveying level to complete the subsequent transmission steps.

Since a plurality of circuit boards 20 need to enter the electroplating tank 120 in sequence, an uneven spacing between the circuit boards 20 may lead to uneven flow of the electroplating solution, thereby causing an electroplating layer to be too thick or too thin in some areas, and affecting the overall performance. The existing apparatus uses a roller conveying structure, but the precision of spacing control is low. As shown in FIG. 5, in an embodiment of the present application, the first linear motor 241 of the first material pushing mechanism 240 is provided with the first material pushing member 242. The first material pushing member 242 is configured to push the circuit board 20, which has been positioned by the first positioning mechanism 230, toward the electroplating tank 120 and catch up with the preceding circuit board 20. An operating gap and a transportation spacing are calculated by the controller, the first positioning mechanism 230 and the first material pushing mechanism 240 are controlled to coordinately cooperate, so that the spacing between two adjacent circuit boards 20 is greater than or equal to 1 mm and less than or equal to 3 mm, that is, the spacing value between two adjacent circuit boards 20 is controlled at a preset value L. For example, the preset value L of the board spacing may be set to 5 mm, 10 mm or 15 mm, etc. However, due to the influence of the control accuracy of mechanical equipment, there is a discrepancy between the spacing value D and the preset value L. Controlled by the linear motor may further reduce an error between the spacing value D and the preset value L compared to conventional roller conveying. specifically, L and D satisfy: L−1.5 mm≤D≤L+1.5 mm, that is, the error may be controlled within the range of 1.5 mm. For example, if the preset value L of the plate spacing is set to 10 mm, then the minimum value of the actual spacing value D may be 8.5 mm, the maximum value of the actual spacing value D may be 11.5 mm, the spacing value D may also be 9.5 mm, or any value within the aforementioned range. Compared with the traditional roller conveying structure, the control is more precise, and the electroplating action is better.

The electroplating action on the existing printed circuit board (PCB) in a single electroplating process is not optimal. A secondary electroplating and a tertiary electroplating are usually required. The primary electroplating and the secondary electroplating will be relatively thin, but a surface of the board is required to be electroplated very evenly, so the primary electroplating and the secondary electroplating are used the horizontal electroplating method, in order to achieve the best electroplating action, the board will be turned over and the pinch edges will be exchanged. Therefore, in the horizontal electroplating production line 10, in order to improve the electroplating efficiency, at least two horizontal electroplating apparatuses 100 are connected front and back, and a flipping device 300 is arranged at a middle of the horizontal electroplating apparatuses 100 to flip the circuit board 20 and convey the circuit board 20. The flipping device 300 receives the circuit board 20 after it has been electroplated by the previous horizontal electroplating apparatus 100, flips the circuit board 20, switches the clamping edge, and conveys the subsequent horizontal electroplating apparatus 100, thereby improving uniformity of the electroplating layer of the circuit board 20.

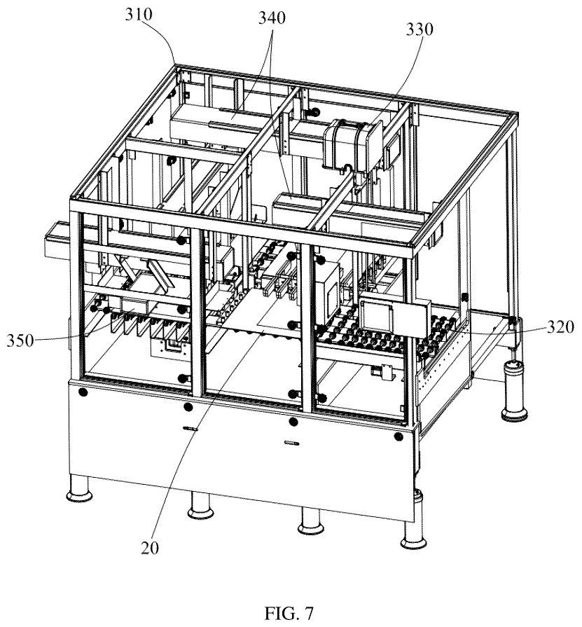

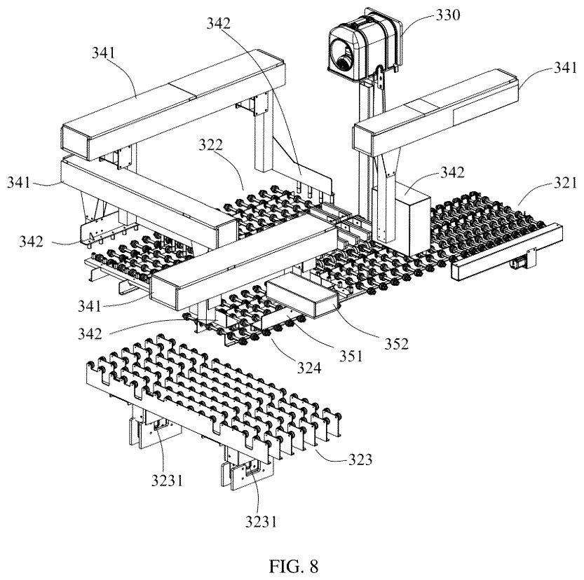

As shown in FIG. 6 to FIG. 10, the flipping device 300 includes a third frame 310, a feeding mechanism 320 and a flipping mechanism 330 arranged at the third frame 310. The feeding mechanism 320 has a conveying track, and the conveying track has a second horizontal conveying surface for horizontally placing the circuit board 20. The second horizontal conveying surface may be aligned with the first horizontal conveying surface. The circuit board 20, after being electroplated by one of the horizontal electroplating apparatuses 100, enters the horizontal conveying surface. The feeding mechanism 320 sends the circuit board 20 to another horizontal electroplating apparatus 100 in the horizontal direction. During the conveying process, the flipping mechanism 330 flips the circuit board 20 on the horizontal conveying surface and swaps a position of a two opposite sides of the circuit board 20, so that the horizontal electroplating conveying devices 130 of the two horizontal electroplating apparatuses 100 clamp the opposite sides of the circuit board 20 respectively.

It should be noted that the horizontal electroplating apparatus 100 electrifies the fixture of the horizontal electroplating conveying device 130 to electroplate the circuit board 20. The current near the clamping point edge of the circuit board 20 close to the horizontal electroplating conveying device 130 is high, thereby resulting in a thicker electroplating layer. While the areas of the circuit board 20 farther from the clamping point of the horizontal electroplating conveying device 130 receive a lower current, thereby resulting in a thinner electroplating layer. Therefore, a single electroplating process cannot achieve a uniform coating. Additionally, the electroplating chemical environment in the electroplating tank 120 differs between an upper surface and a lower surface of the circuit board 20, so that the electroplating effects on the two surfaces are also different. In the present embodiment, the flipping device 300 is provided to flip the circuit board 20, switch the clamping point to the opposite side, so that after the circuit board 20 undergoes electroplating in two horizontal electroplating apparatuses 100, the electroplating layer becomes more uniform, thereby effectively improving the production quality of the circuit board 20.

The second horizontal conveying surface of the feeding mechanism 320 may be formed by structures such as a belt conveying line, a roller conveying line, or a roller and friction drive conveying line. The circuit board 20 moves in the horizontal direction from the previous horizontal electroplating apparatus 100 to the electroplating tank 120 of the next horizontal electroplating apparatus 100 in the second horizontal conveying surface, thereby allowing the horizontal electroplating conveying device 130 to accurately clamp the circuit board 20, and ensuring the stability of the connection and transportation process.

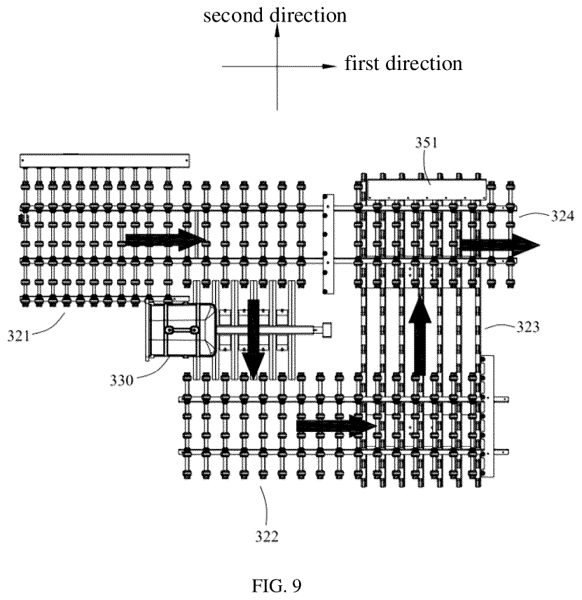

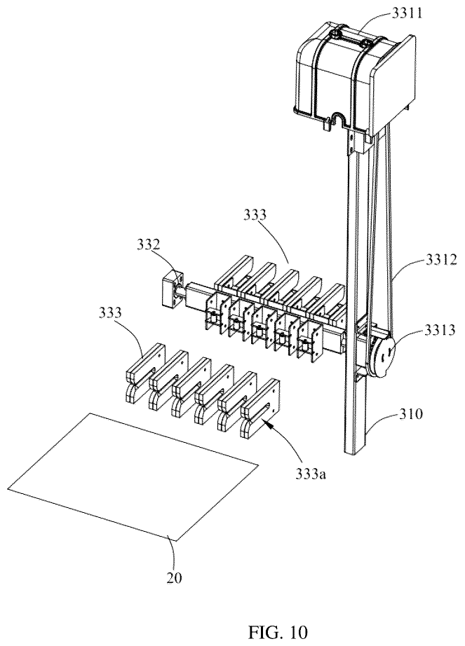

Referring to FIG. 9 and FIG. 10, in one embodiment of the present application, the flipping mechanism 330 includes a driving assembly 331, a rotating shaft 332, and a clamping assembly 333. The feeding mechanism 320 conveys the circuit board 20 in the first direction, and the rotating shaft 332 is also extended along the first direction. The clamping assembly 333 is arranged at the rotating shaft 332, and the driving assembly 331 is configured to drive the rotating shaft 332 and the clamping assembly 333 to rotate. The clamping assembly 333 is provided with a slot 333a, the slot 333a extends along an axial direction of the rotating shaft 332 and can be aligned with a horizontal conveying surface of the feeding mechanism 320. When the feeding mechanism 320 conveys the circuit board 20 to the flipping mechanism 330, a side edge of the circuit board 20 is inserted into the slot 333a. The driving assembly 331 drives the rotating shaft 332 to rotate, the clamping assembly 333 flips the circuit board 20 by 180° then places the circuit board 20 back onto the second horizontal conveying surface of the feeding mechanism 320. At this point, the circuit board 20 is flipped, the two side edges of the circuit board 20 along the first direction are swapped, so that the side edges of the circuit board 20, clamped by the electroplating conveying mechanism 132 in the two horizontal electroplating apparatuses 100, are located on opposite sides to ensure uniform electroplating.

In an embodiment, the driving assembly 331 includes a driving motor 3311, a transmission belt 3312, and a transmission wheel 3313. Specifically, one end of the rotating shaft 332 is connected to the transmission wheel 3313. The driving motor 3311 is arranged at a bracket and is connected to the transmission wheel 3313 through the transmission belt 3312. The driving motor 3311 drives the transmission wheel 3313 to rotate through the transmission belt 3312, thereby causing the transmission wheel 3313 to drive the rotating shaft 332 to rotate in the first direction and drive the clamping assembly 333 to flip the circuit board 20. The cost of the driving motor 3311 and the transmission belt 3312 is relatively lower compared to the gear, the structure of the transmission belt 3312 may absorb vibrations, reducing noise, reducing noise and being quieter than the gear, with maintenance also being more convenient and simpler. In other embodiments of the present application, the driving assembly 331 may also adopt other structures, such as a worm gear set, without specific limitations.

In an embodiment, the feeding mechanism 320 includes a first conveying line 321, a second conveying line 322, a third conveying line 323, and a fourth conveying line 324. The first conveying line 321, the second conveying line 322, and the fourth conveying line 324 each use the friction wheel arranged at the roller to form a horizontal conveying surface. The rotation of the roller drives the friction wheel to rotate, the friction wheel drives the circuit board 20 to move in the first direction. The first conveying line 321, the second conveying line 322, and the fourth conveying line 324 are arranged at intervals and extend along the first direction. The flipping mechanism 330 is arranged between the first conveying line 321 and the second conveying line 322. The third conveying line 323 is arranged along the second direction, and both ends of the third conveying line 323 are connected to the second conveying line 322 and the fourth conveying line 324 respectively. The third conveying line 323 is ascended and descended by a cylinder mechanism to lift the circuit board 20 on the second conveying line 322. Specifically, when the circuit board 20 moves from the first conveying line 321 into the slot 333a of the clamping assembly 333, the flipping device 300 flips the circuit board 20 by 180° and convey it to the second conveying line 322, the circuit board 20 continues to move in the first direction on the second conveying line 322 until it reaches above the third conveying line 323, The second lifting mechanism 3231 ascends the third conveying line 323 to lift the circuit board 20. The circuit board 20 then moves in the second direction on the third conveying line 323 until it reaches above the fourth conveying line 324. The cylinder descends the third conveying line 323, and the circuit board 20 falls onto the fourth conveying line 324 and moves in the first direction towards the electroplating tank 120.

The flipping device 300 also includes a second material pushing mechanism 340 and a second positioning mechanism 350. The second material pushing mechanism 340 includes four third linear motors 341, each of the third linear motors 341 is provided with a third material pushing member 342. The four third linear motors 341 and four third material pushing members 342 are respectively arranged along four conveying lines, so as to push the circuit board 20 on the corresponding conveying line to move along the conveying direction of the conveying line. In an embodiment, the fourth conveying line 324 is also provided with a second positioning mechanism 350, the second positioning mechanism 350 includes a second positioning baffle 351. When the third material pushing member 342, located at the third conveying line 323, pushes the circuit board 20 along the second direction to the fourth conveying line 324, the circuit board 20 abuts against the second positioning baffle 351 of the second positioning mechanism 350, thereby aligning the side of the circuit board 20 with the horizontal electroplating conveying device 130 of the next horizontal electroplating apparatus 100, and ensuring the consistency of the clamping point position. In the present embodiment, the second positioning baffle 351 is also connected to a fourth linear motor 352, so that adjust the position of the second positioning baffle 351 on the fourth conveying line 324, thereby accommodating the circuit boards 20 of different specifications.

Additionally, the third linear motors 341 and third material pushing members 342 located at the fourth conveying line 324 push the positioned circuit board 20 towards the electroplating tank 120. During the pushing process, the control system will calculate a spacing moved by the previous positioned circuit board 20, and push the circuit board 20 on the second positioning mechanism 350 to catch up with the previous circuit board 20, thereby controlling a spacing between them. It should be noted that, in order to ensure uniform electroplating quality, the second material pushing mechanism 340 of the flipping device 300 also uses a linear motor, which may control a spacing error between two adjacent positioned circuit boards 20 to within 1.5 mm. That is, the actual spacing value D of the circuit board and the preset spacing value L satisfy: L−1.5 mm≤D≤L+1.5 mm. For example, if the preset spacing value L is set to 10 mm, the actual spacing value D may range from a minimum of 8.5 mm to a maximum of 11.5 mm, and values such as 9.5 mm or any value within the aforementioned range being acceptable, thereby ensuring that the spacing between the circuit boards 20 entering the front and rear two horizontal electroplating apparatuses 100 remain within the same range, and minimizing the impact caused by spacing errors during secondary electroplating.

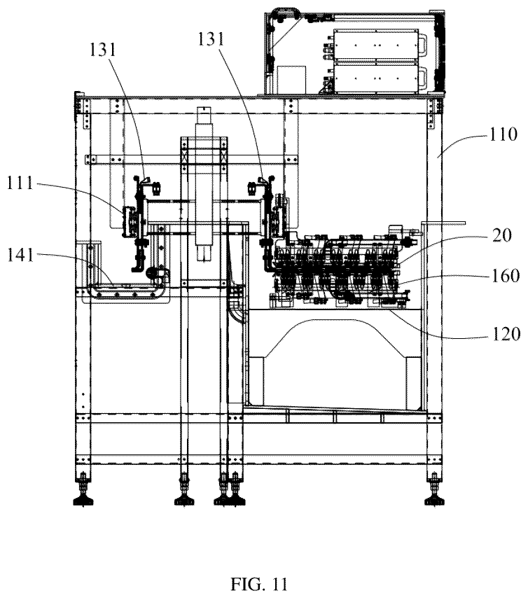

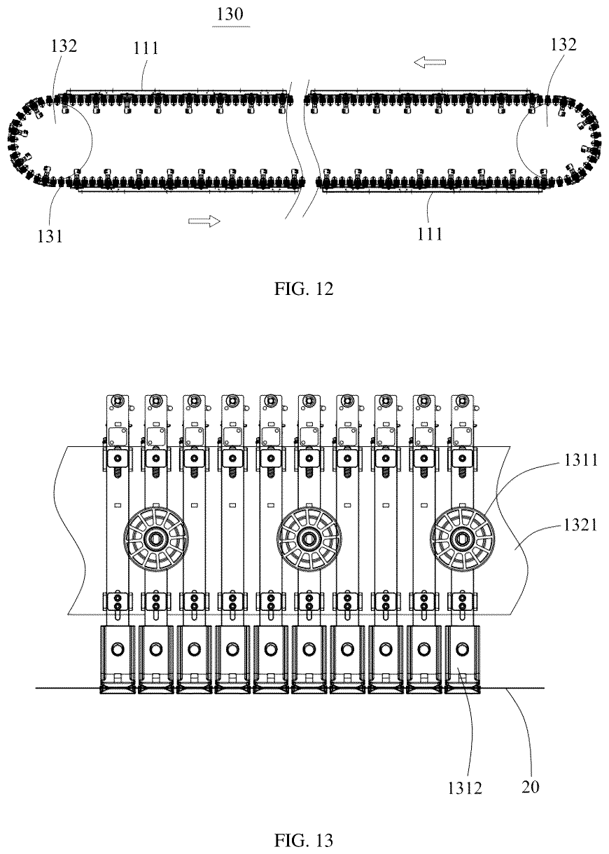

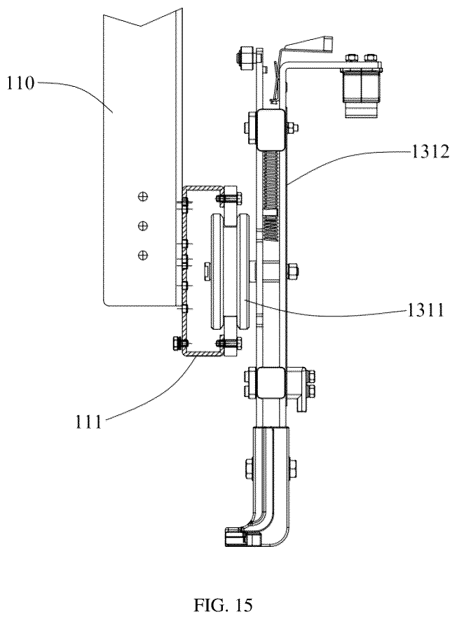

As shown in FIG. 11 to FIG. 15, in an embodiment of the present application, the horizontal electroplating conveying device 130 also includes a clamping mechanism 131 and an electroplating conveying mechanism 132. The first frame 110 provides an overall structural support for the horizontal electroplating apparatus 100. The first frame 110 is provided with a rail 111 to guide the sliding member 1311 to perform a linear motion. The main purpose of the rail 111 arranged at the first frame 110 is to ensure that the clamping mechanism 131 may move smoothly and accurately along a predetermined path, which is crucial for preventing damage or positional deviations of the circuit board 20 during the electroplating process. The rail 111 may keep the clamping mechanism 131 on the correct track, thereby preventing a machining error caused by misalignment. By reducing the vibrations or oscillations of the sliding member 1311 during movement, the stability of the circuit board 20 is ensured during the conveying process. The rail 111 may reduce a friction between the clamping mechanism 131 and other members, thereby extending the lifespan of the equipment.

The clamping mechanism 131 includes a plurality of sliding members 1311 and clamping members 1312. The sliding members 1311 are slidably connected to the rails 111 on the first frame 110, while the clamping members 1312 are responsible for fixing the circuit board 20. The electroplating conveying mechanism 132 is configured to drive the clamping mechanism 131, causing the sliding members 1311 to move along the rail 111, thereby enabling the convey of the circuit board 20 along a production line. Specifically, the clamping mechanism 131 first clamps the circuit board 20 to be processed through the clamping members 1312. After the electroplating conveying mechanism 132 is activated, which drives the sliding members 1311 to move along a direction of the rail 111. The movement of the sliding members 1311 causes the clamping members 1312 and the circuit board 20 thereon to move correspondingly, thereby completing a convey of the circuit board 20 between the electroplating tanks. The main purpose of this design is to achieve the automated convey of the circuit board 20 in the electroplating production line, thereby reducing manual operation and improving production efficiency and safety. At the same time, this design allows the apparatus to accommodate the circuit boards 20 of different sizes and shapes, offering better versatility and flexibility.

It can be understood that the rail 111 is typically a long strip-shaped structure made of metal, which can be an open T-slot or a closed V-slot, the sliding member 1311 has a corresponding slider that matches with the rail 11. Alternatively, a roller or a ball bearing can be configured to reduce friction, making it suitable for applications requiring frequent reciprocating motion. Another option is a design consisting of the rail 111 and slider, the slider contains a roller or a ball, enabling smooth movement in the rail 111. It should be understood that the structural design of the sliding member 1311 typically requires consideration of the fitting method with the rail 111, which may be a metal or a plastic slider that engages with the rail 111 or guide groove, and may contain a ball or a needle to reduce friction. Alternatively, a roller design, it may be a roller, a sliding member 1311 with a wheel, which can roll on the surface of the rail 111 to reduce friction and provide smooth movement. Another option is a suspended design, where the sliding member 1311 is connected to the upper rail 111 through a suspended manner, which is suitable for vertical or inclined movements. This configuration enables precise and stable convey of the circuit board 20 during the electroplating process. The sliding member 1311 is part of the guidance system, and its in cooperation with the rail 111 may ensure that the circuit board 20 does not deviate or vibrate during movement, thereby ensuring electroplating quality and production efficiency. The stable mechanical convey reduces the likelihood of product damage or an uneven electroplating due to improper manual handling. And through automated transmission, it reduces the time of manual handling, increases production speed, improves the production efficiency and product quality, and reduces production costs and safety risks.

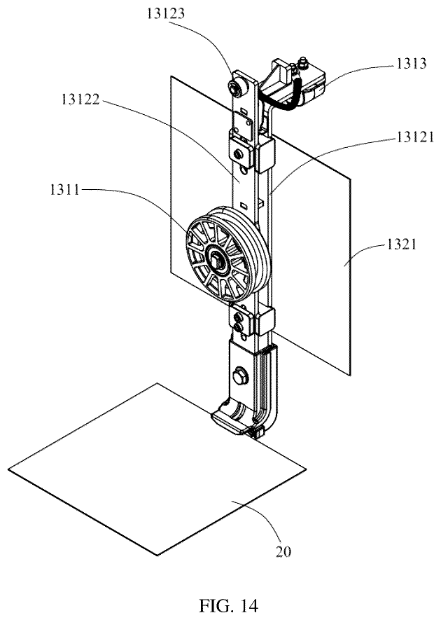

Referring to FIG. 14 to FIG. 16, the clamping member 1312 includes a fixing clamp 13121, a movable clamp 13122, and a lifting support wheel 13123. The movable clamp 13122 is movably mounted at the fixing clamp 13121 through a connecting assembly, and the movable clamp 13122 is configured to cooperate with the fixing clamp 13121 to clamp the circuit board 20. The lifting support wheel 13123 is arranged at a side of the movable clamp 13122 away from the fixing clamp 13121, and the lifting support wheel 13123 is configured to drive the movable clamp 13122 to ascend or descend. The first frame 110 is provided with a guide assembly along a first direction, the guide assembly includes a first guide member 112 and a second guide member 113. Upper surfaces of the first guide member 112 and second guide member 113 are respectively formed with an inclined plane and extend upwardly along the conveying direction. When the lifting support wheel 13123 reaches the inclined plane, the lifting support wheel 13123 moves upward along the inclined plane. The fixing clamp 13121 is fixedly mounted at the electroplating conveying mechanism 132, so that the electroplating conveying mechanism 132 moves the entire device horizontally through the fixing clamp 13121. When the lifting support wheel 13123 moves to a lowest point of the inclined plane, the lifting support wheel 13123 begins to climb upward along the inclined plane. Since the fixing clamp 13121 being rigidly connected to the electroplating conveying mechanism 132 and always maintaining at the same horizontal height, the movable clamp 13122 moves upward under the drive of the lifting support wheel 13123, causing relative sliding between the movable clamp 13122 and the fixing clamp 13121, thereby opening the movable clamp 13122 and the fixing clamp 13121.

As shown in FIG. 16, when the clamping mechanism 131 moves along a guide slope of the first guide member 112 in a feeding direction, the lifting support wheel 13123 ascends, a spacing between the fixing clamp 13121 and the movable clamp 13122 will increase, thereby allowing the circuit board 20 to be successfully clamped. When the clamping mechanism 131 moves in a opposite direction (i.e., the unloading direction) along the guide slope of the second guide member 113, the spacing between the fixing clamp 13121 and the movable clamp 13122 also increases, but this time it is to release the circuit board 20 from the clamping state. Specifically, when the clamping mechanism 131 is at its initial position, the spacing between the fixing clamp 13121 and the movable clamp 13122 is appropriate for clamping the circuit board 20. In the feeding stage, the circuit board 20 is placed in the position of the clamping mechanism 131. The clamping mechanism 131 starts to move along the rail 111 and slides to the first guide member 112. Under the action of the guide slope of the first guide member 112, the spacing between the fixing clamp 13121 and the movable clamp 13122 gradually increases. This increased spacing allows the circuit board 20 to smoothly enter a space between the two clamping assemblies 333. After the clamping mechanism 131 fully passes through the first guide member 112, the spacing between the fixing clamp 13121 and the movable clamp 13122 is restored, thereby the circuit board 20 is securely clamped. The clamping mechanism 131 continues to move along the rail 111, entering the electroplating tank or other treatment area. During this stage, the circuit board 20 undergoes electroplating or other surface treatment. In the unloading stage, after the treatment is completed, the clamping mechanism 131 begins to return, and slides along the rail 111 to the second guide member 113. Under the action of the guide slope of the second guide member 113, the spacing between the fixing clamp 13121 and the movable clamp 13122 gradually increases again. This increased spacing allows the circuit board 20 to be released from the clamped state. After the clamping mechanism 131 fully passes through the second guide member 113, the circuit board 20 is lowered or conveyed to the next process. The clamping mechanism 131 returns to its initial position, ready for the next cycle. This process ensures that the circuit board 20 is securely clamped and released during the electroplating process, while also ensuring the continuity and automation of the entire process flow.

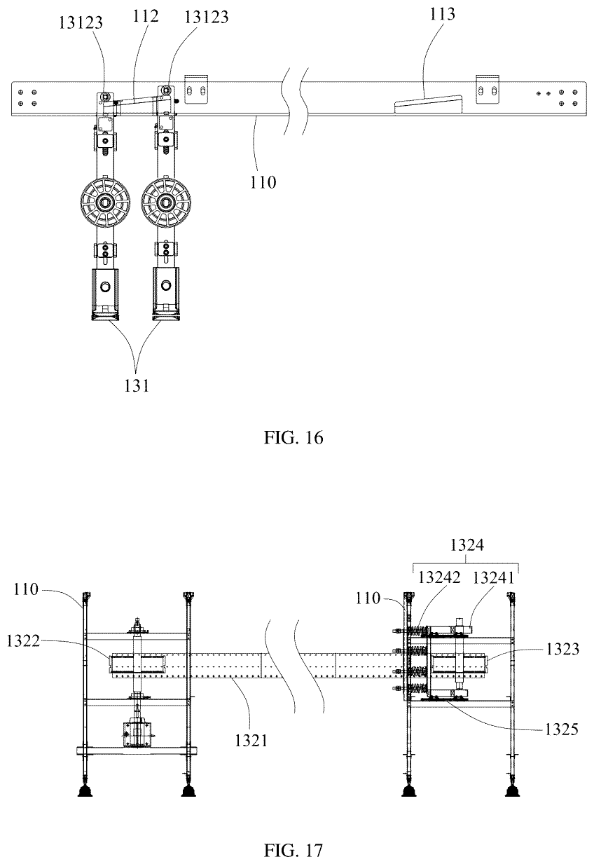

As shown in FIG. 17 and FIG. 18, the electroplating conveying mechanism 132 further includes a conveying steel belt 1321, a driving mechanism, and a tensioning mechanism 1324. The conveying steel belt 1321 is mounted at the first frame 110 and is capable of sliding along the first frame 110. The driving mechanism includes a conveying driving wheel 1322 and a conveying driven wheel 1323, the conveying driving wheel 1322 and the conveying driven wheel 1323 are located at two ends of the first frame 110, and the conveying driving wheel 1322 and the conveying driven wheel 1323 are connected through the conveying steel belt to form a closed-loop transmission. An outer surface of the conveying steel belt 1321 is provided with a clamping mechanism 131 to enable continuous conveying. The tensioning mechanism 1324 is elastically connected to both the conveying steel belt 1321 and the first frame 110. By adjusting the horizontal spacing between the first frame 110 and the conveying steel belt 1321 through elastic deformation, thereby ensuring the tension state of the steel belt. Specifically, before the device is started, the conveying steel belt 1321 is in its initial position, the tensioning mechanism 1324 maintains a certain preset tension, thereby ensuring that the conveying steel belt 1321 on the first frame 110 is a properly tensioned state. When the device is activated, the conveying driving wheel 1322 begins to rotate. Since the conveying driving wheel 1322 and the conveying driven wheel 1323 form a closed-loop drive through the conveying steel belt 1321, the conveying driven wheel 1323 also rotates. The conveying steel belt 1321 slides along the first frame 110 under the drive of the driving mechanism, clamps the circuit board 20 to be electroplated through the clamping mechanism 131 and pulls it into the next process. The circuit board 20 moves forward along with the movement of the conveying steel belt 1321.

In an embodiment, the tensioning mechanism 1324 includes a tensioning seat 13241 and a compression spring 13242. The compression spring 13242 is sleeved on the tensioning seat 13241, and the tensioning seat 13241 is slidably mounted at the first frame 110 through a slide rail assembly 1325. One end of the compression spring 13242 abuts against the tensioning seat 13241, while the other end of the compression spring 13242 abuts against the first frame 110, which provides a tensioning action. The design allows the position of the conveying driven wheel 1323 relative to the first frame 110 to be automatically adjusted through the elasticity of the compression spring 13242, thereby maintaining the tension of the conveying steel belt 1321 to ensure smooth convey of the multiple clamping members 1312 on the outer side of the steel belt and prevent sagging or deviation.

The existing copper stripping process for fixtures typically involves using chemical agents such as nitric acid or sulfuric acid combined with hydrogen peroxide to strip the copper layer, and the fixtures are stripped using a closed clamping part. The contact area of the chemical is small, thereby leading to suboptimal stripping effects and often leaves copper residue.

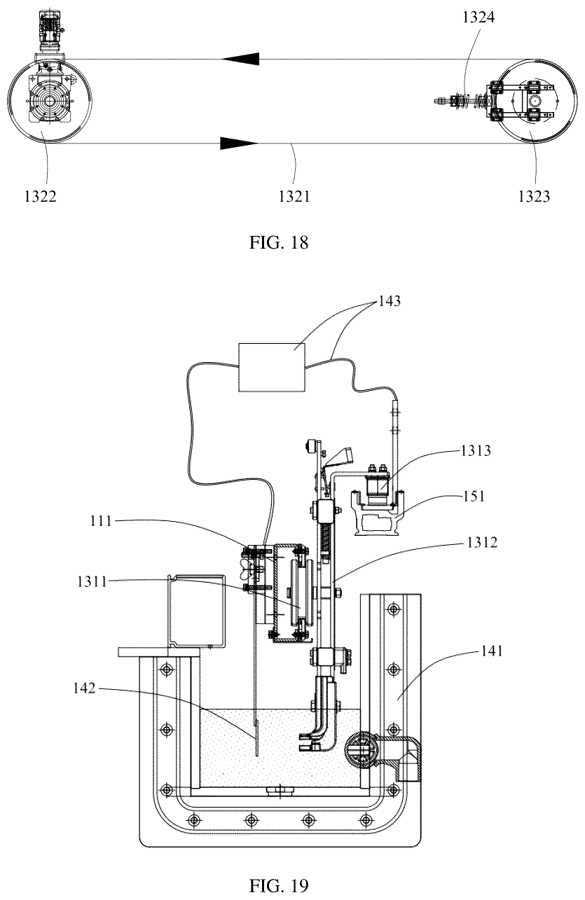

As shown in FIG. 19, the present solution provides a cathode conductive clamp reverse stripping device 140, the cathode conductive clamp reverse stripping device 140 includes a deplating tank 141 and a stripping assembly 142 arranged at the first frame 110. The first frame 110 has a deplating station and a conveying station, and a convey track connecting the deplating station and the convey station. The deplating tank 141 and the electroplating tank 120 are arranged at opposite sides of the conveying steel belt 1321 in the first direction. The deplating station is arranged in the deplating tank 141, and the convey station is arranged in the electroplating tank 120. The convey track is formed by the conveying steel belt 1321, and the clamping member 1312 is movably arranged at the convey track. When the clamping member 1312 moves from the conveying station to the deplating station, the lifting support wheel 13123 of the clamping member 1312 ascends through the second guide member 113. The fixing clamp 13121 engages the movable clamp 13122 through an engaging block, thereby maintaining both the fixing clamp 13121 and the movable clamp 13122 remain in an open state. The stripping assembly 142 is inserted into the deplating tank 141, and the deplating tank 141 contains a stripping solution. The champing member 1312 and the stripping assembly 142 are respectively electrically connected to the power supply system 143, thereby the stripping assembly 142 forms a cathode and the champing member 1312 forms an anode, and the two create a conductive circuit to strip the electroplated material from the champing member 1312. The stripping solution may be set as an iron-based copper electroplating solution, thereby replacing the existing solutions that use nitric acid or sulfuric acid combined with hydrogen peroxide for stripping.

When the clamping member 1312 and the stripping assembly 142 are simultaneously powered, the iron-based copper electroplating solution forms a conductive circuit with the charged clamping member 1312 and the stripping assembly 142, so that the copper on the clamping member 1312 undergoes an electrolytic reaction, causing copper ions to be stripped from the clamping member 1312 enter the solution. Some of the copper ion deposit at a surface of the stripping assembly 142 to form a copper layer, another of the copper ion remain in the solution. The stripping process realizes the stripping of the copper on the clamping member 1312 and conveys the copper to the stripping assembly 142, and also promotes the balance of ionic members within the stripping chemical, thereby ensuring that when the clamping member 1312 inadvertently carries the stripping chemical, into the next electroplating step, the stripping solution will not corrode the electroplating tank 120, nor the stripping chemical carried by the clamping member 1312 will contaminate the electroplating chemical within the electroplating tank 120.

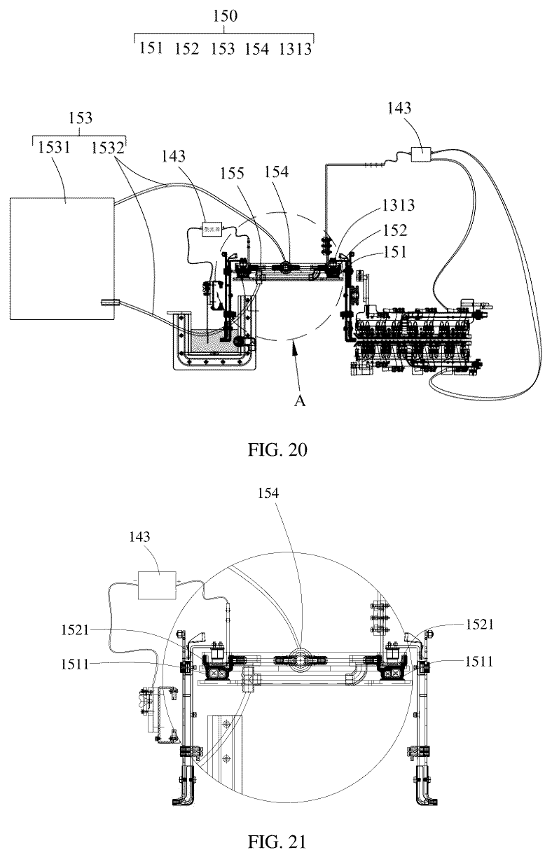

As shown in FIG. 20 and FIG. 21, in an embodiment of the present application, the horizontal electroplating apparatus 100 also includes a cathode conductive device 150, the cathode conductive device 150 includes a conductive oil groove assembly 151, a cathode assembly 152, a conductive slider assembly 1313, and a re-circulating mechanism 153. The conductive oil groove assembly 151 contains a conductive oil to create a conductive medium environment. The cathode assembly 152 is connected to an anode of the power supply, forming a part of the current circuit. The conductive slider assembly 1313 is mounted at the clamping mechanism 131 and is submerged in the conductive oil in the conductive oil groove assembly 151. The conductive slider assembly 1313 is electrically connected to the cathode assembly 152 and is responsible for conducting the current from the cathode assembly 152 to the clamping mechanism 131, thereby electrifying the circuit board 20. The re-circulating mechanism 153 includes an oil collecting groove 1531 and a re-circulating assembly 1532. The oil collecting groove 1531 is configured to store the conductive oil. The conductive oil groove assembly 151 is connected to the oil collecting groove 1531 through the re-circulating assembly 1532, thereby forming a circulating passage for the conductive oil. Specifically, the anode of the power supply is connected to the cathode assembly 152 to form the current circuit. The conductive slider assembly 1313, submerged in the conductive oil in the conductive oil groove assembly 151, is electrically connected to the cathode assembly 152. The current is conveyed to the clamping mechanism 131 through the conductive slider assembly 1313, thereby electrifying the circuit board 20.

In the working process, the conductive oil in the conductive oil groove assembly 151 may need to be replaced or replenished due to temperature changes or other factors. The re-circulating assembly 1532 establishes a circulating passage between the conductive oil groove assembly 151 and the oil collecting groove 1531. When the conductive oil needs to be replaced or replenished, the conductive oil in the oil collecting groove 1531 flows into the conductive oil groove assembly 151 through the re-circulating assembly 1532, and vice versa, thereby enabling the recycling of the conductive oil. The solution uses conductive oil as a medium for current transmission, while the re-circulating mechanism 153 ensures the recycling of the conductive oil, thereby maintaining stable current convey and effective management of the conductive oil during the horizontal electroplating process, which not only improves electroplating efficiency but also reduces resource waste, enhances equipment reliability, and increases maintenance efficiency. The core of the entire solution is the use of conductive oil as a medium in the electroplating process and to achieve the recycling of conductive oil through a re-circulating mechanism 153, which helps maintain current stability and conductivity during electroplating, while reducing resource consumption and costs through the recycling of the conductive oil. Furthermore, the design minimizes mechanical wear, thereby improving the system's reliability and service life.

The cathode conductive device 150, in addition to including a conductive oil groove assembly 151, a cathode assembly 152, a conductive slider assembly 1313, a re-circulating mechanism 153, and an oil supply mechanism 154. The main function of the oil supply mechanism 154 is to provide fresh conductive oil from an external source to the conductive oil groove assembly 151, thereby ensuring a continuous supply of conductive oil and a proper operation of the system. When the conductive oil in the conductive oil groove assembly 151 needs to be replenished or replaced, the oil supply mechanism 154 conveys new conductive oil to the conductive oil groove assembly 151. The presence of the oil supply mechanism 154 ensures that the conductive oil groove assembly 151 always has an adequate supply of conductive oil, maintaining the normal functioning of the system even during prolonged operation or under heavy consumption. The replenishment of conductive oil may maintain the purity of the conductive oil, thereby improving the quality and efficiency of the electroplating process. By automatically replenishing the conductive oil through the oil supply mechanism 154, thereby reducing the frequency of manual oil addition, simplifying maintenance tasks, and enhancing the reliability and operational convenience of the equipment.

The re-circulating mechanism 153 includes an oil collecting groove 1531, a re-circulating assembly 1532, and an overflow assembly 155. The overflow assembly 155 has an overflow port, the overflow assembly 155 is connected to the conductive oil tank assembly through the overflow port. The conductive oil groove assembly 151 is connected to the oil collecting groove 1531 through the overflow assembly 155. The conductive oil groove assembly 151 has a preset volume, when the liquid volume in the conductive oil groove assembly 151 exceeds the preset volume, the conductive oil in the conductive oil groove assembly 151 may flow into the oil collecting groove 1531 through the overflow assembly 155. The automatic overflow and circulation of the conductive oil is achieved through the overflow assembly 155, thereby ensuring that the liquid volume in the conductive oil groove assembly 151 does not exceed the preset volume limit. It can be understood that the overflow assembly 155 can be connected to the conductive oil groove assembly 151 and the oil collecting groove 1531 through a pipe. The pipe between the overflow port and the conductive oil groove assembly 151 ensures that the conductive oil flows smoothly into the overflow assembly 155. The pipe between the overflow assembly 155 and the oil collecting groove 1531 ensures that the conductive oil flows into the oil collecting groove 1531.

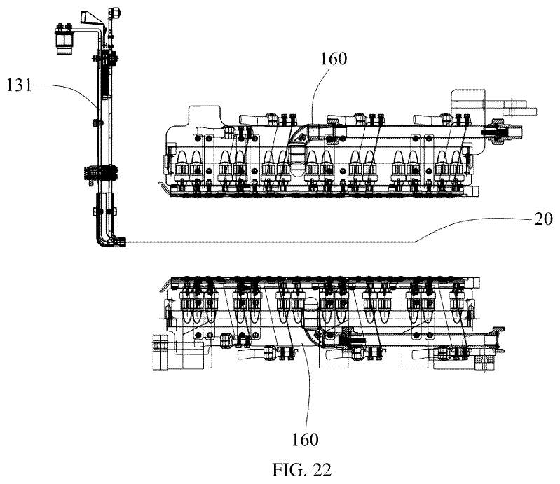

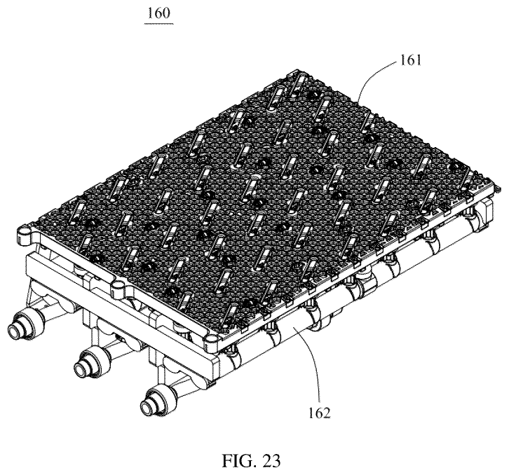

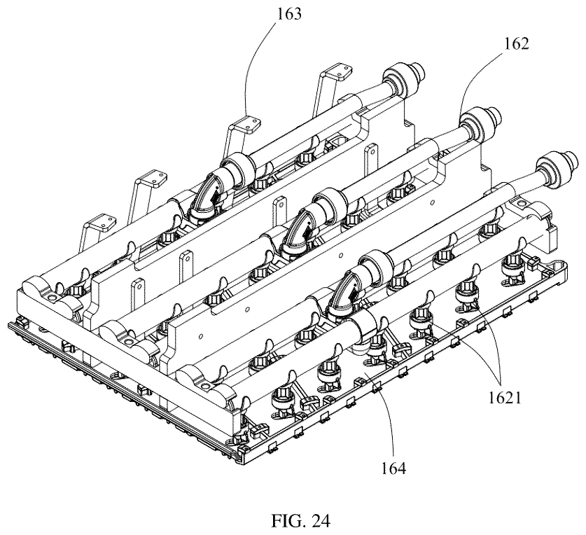

As shown in FIG. 22 to FIG. 25, the horizontal electroplating apparatus 100 also includes an anode spray device 160 arranged in the electroplating tank 120, the anode spray device 160 includes an anode mesh well plate 161, a spray assembly 162, and a conductive assembly 163. The anode mesh 164 is detachably arranged on a side of the anode mesh well plate 161 close to the spray assembly 162 and is configured to be submerged in an electrolyte containing electroplating metal ions together with the circuit board 20. The anode mesh 164 is connected to a power source to form a potential difference between the anode mesh 164 and the circuit board 20, thereby inducing an electrolytic reaction, so that the outer surface of the circuit board 20 is electroplated with a metal coating. The spray assembly 162 is configured to spray the reaction solution on the circuit board 20. The spray assembly 162 has a plurality of spray pipes, the spray pipe is provided with a plurality of nozzles 1621. The spray pipe is connected to the reaction solution and discharge the solution through the nozzles 1621. The one end of the conductive assembly 163 is connected to a rectifier, and the other end of the conductive assembly 163 is connected to the anode mesh 164 to supply power to the anode mesh 164, thereby enabling the conductive assembly 163 to perform electroplating.

In the embodiment of the present application, at least two sets of anode spray devices 160 are arranged at intervals in the vertical direction in the electroplating tank 120. Each of the anode spray devices 160 has a spraying surface. The spraying surfaces of the two sets of anode spray devices 160 are arranged oppositely, with a gap between the two sets of anode spray devices 160, thereby forming an electroplating chamber for the movement of the circuit board 20 during electroplating. A plurality of anode spray devices 160 are sequentially arranged above and below the moving path of the circuit board 20. As the circuit board 20 moves through the electroplating chamber, the anode spray devices 160 on both the upper and lower sides spray the reaction solution, thereby ensuring that both the upper and lower sides of the circuit board 20 are uniformly electroplated. In present embodiment, a plurality of sets of anode spray devices 160 are arranged at intervals in the horizontal direction, each of the sets of anode spray devices 160 is tightly arranged at a same height, thereby reducing the gap between the device sets, and allowing the circuit board 20 to be continuously electroplated without interruption during its movement until the electroplating process is complete.

It should be noted that the anode spray devices 160 are part of the anode conductive section of the apparatus. After assembly, the anode spray devices 160 are fixed in the electroplating tank 120, the reaction solution is then added to the electroplating tank 120, the anode spray devices 160 are submerged in the reaction solution, and the circuit board 20 is placed between the anode spray devices 160 through a horizontal electroplating fixture. Then, the power is applied to establish a conductive connection, and the circuit board 20 is electroplated. The anode mesh well plate 161 is an auxiliary device used in the horizontal electroplating apparatus 100 to assist in the electroplating process. The action of the anode mesh well plate 161 is to provide a uniform current density distribution for the workpiece during electroplating and to decompose the elemental particles in the reaction solution, attaching them to the circuit board 20.

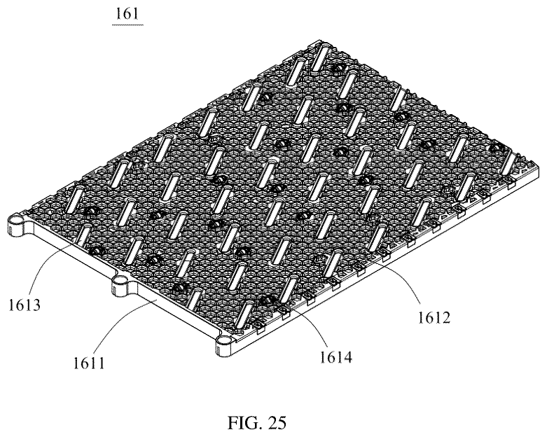

Referring to FIG. 25, in an embodiment of the present application, the anode mesh well plate 161 includes: a well plate body 1611 and a guide wheel 1614. The well plate body 1611 is provided with a plurality of meshes 1612 and a plurality of first spray holes 1613. Each of the meshes 1612 is arranged in a hexagonal shape, the meshes 1612 are arranged in a honeycomb array at the well plate body 1611. A plurality of first spray holes 1613 are arranged at intervals at the well plate body 1611. The well plate body 1611 has a spraying side facing the circuit board 20 and spraying the circuit board 20. The guide wheel 1614 is mounted at the spraying side of the well plate body 1611 and configured to contact the circuit board 20.

In the present embodiment, the well plate body 1611 of the anode mesh well plate 161 is arranged in the horizontal direction to be parallel to the circuit board 20, thereby allowing the circuit board 20 to slide between the anode mesh well plates 161 along a preset direction. The meshes 1612 are configured to increase a light transmission during the electroplating of the circuit board 20. An electroplating anode with good light transmission may improve the efficiency and quality of the electroplating process. The electroplating anode plays a catalytic role during the electroplating process, a thin layer of metal or alloy is deposited at the metal surface through electrolysis action. The light transmission provided by the meshes 1612 on the anode mesh well plate 161 may assist in the uniform deposition of metal during the electroplating process. The meshes 1612 on the anode mesh well plate 161 are of hexagonal shape, the adjacent meshes 1612 to be tightly arranged through using the geometric properties of the regular hexagon, so that the meshes 1612 may be arranged in a honeycomb pattern on the well plate body 1611 to reduce the an obstruction area between adjacent meshes 1612, thereby contributing to a light is evenly distributed on the electroplating surface, ensuring uniform deposition of the electroplating layer, and preventing issues with local over-thickness or under-thickness.

Additionally, compared to other shapes that can be tightly arranged, the hexagonal shape has more edges and is closer to a circular form, providing greater light transmission, and ensuring uniform light transmission across each segment compared to a regular triangle or a square. The good light transmission of the meshes 1612 may also reduce a shadowed area during the electroplating process, thereby preventing the formation of rough or uneven surfaces, and improving the electroplating quality. The first spray hole 1613 is configured to spray the reaction solution. During electroplating, a pipe carrying the reaction solution is joined to an outlet of the first spray hole 1613, thereby allowing the solution to be sprayed onto the surface of the circuit board 20 through the first spray hole 1613. The arrangement of the first spray hole 1613 enables a wider spray range for the reaction solution, thereby more evenly distributing the solution on the surface of the circuit board 20, ensuring that metal ions can adhere more uniformly to the surface of the circuit board 20, and leading to a more uniform electroplating layer. Moreover, the anode mesh well plate 161 is also provided with a plurality of guide wheels 1614 at intervals to prevent the circuit board 20 from contacting with a surface of the anode mesh well plate 161 due to gravitational factors or other forces, which could cause friction and scratching of the circuit board 20.

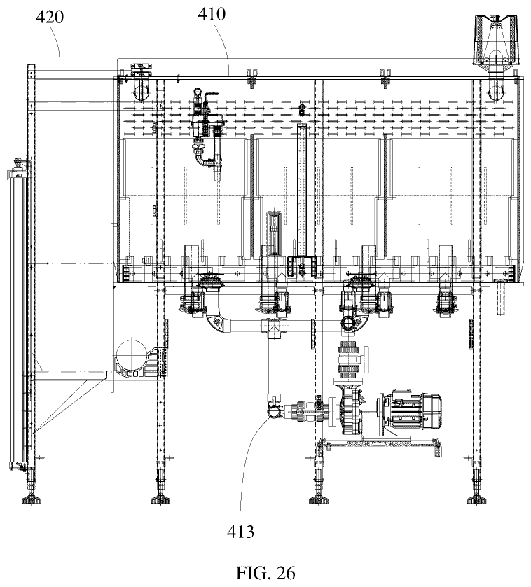

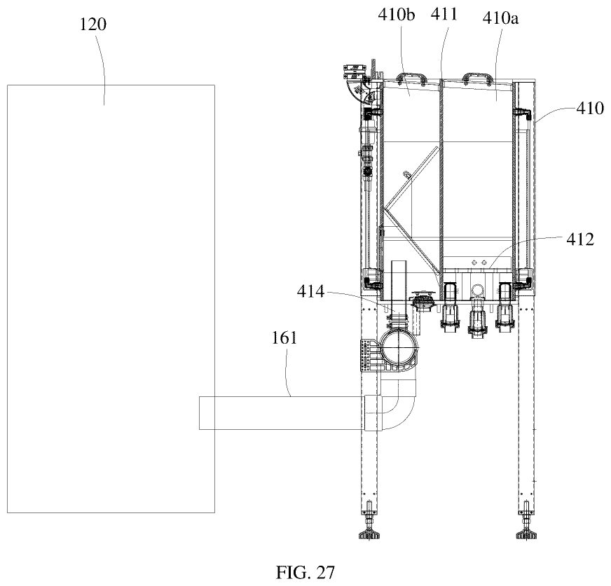

Referring to FIG. 26 and FIG. 27, in one embodiment of the present application, the horizontal electroplating production line 10 also includes a copper dissolving device 400, the copper dissolving device 400 is configured to dissolve a pure copper through the reaction solution and react to generate an electroplating solution. The copper dissolving device 400 includes: a copper dissolving tank 410, a conveying pipeline 413, and an overflow mechanism 414. The copper dissolving tank 410 is provided with a divider plate 411, and the divider plate 411 divides the copper dissolving tank 410 into a first tank body 410a and a second tank body 410b. The first tank body 410a has an inlet for the reaction solution to enter, and a copper particle basket 412 for placing pure copper. The upper part of the divider plate 411 is provided with an overflow portion that connects the first tank body 410a with the second tank body 410b. The second tank body 410b is provided with an overflow outlet for the electroplating solution to flow out. The conveying pipeline 413 connects the second tank body 410b with the first tank body 410a, so that the first tank body 410a, the overflow portion, the second tank body 410b, and the conveying pipeline 413 are connected to form an internal circulation loop. The overflow mechanism 414 is mounted at the overflow outlet, and the overflow mechanism 414 is configured to convey the liquid from the second tank body 410b to the electroplating tank 120.

In the present embodiment, the copper dissolving tank 410 is configured to contain the reaction solution and facilitate the chemical reaction, the reaction solution and the pure copper react in the copper dissolving tank 410 to generate an electroplating solution that can be used for electroplating. The conveying pipeline 413 is configured to extract the liquid from the second tank body 410b to the first tank body 410a. The liquid in the first tank body 410a flows into the second tank body 410b through the overflow portion arranged at the top of the divider plate 411. The conveying pipeline 413 cooperates with the overflow portion at the top of the divider plate 411 to realize an internal circulation of the liquid in the copper dissolving tank 410. The reaction solution enters the first tank body 410a through an inlet of the first tank body 410a. When the liquid level in the first tank body 410a reaches the overflow portion, the liquid flows into the second tank body 410b through the overflow portion. The convey pipeline is connected to a bottom of the second tank body 410b. The liquid overflowing from the first tank body 410a to the second tank body 410b flows back to the first tank body 410a through the convey pipe, thereby forming an internal circulation in the copper dissolving tank 410. The overflow mechanism 414 is configured to flow the electroplating solution formed by the reaction into the electroplating tank 120 by overflow.

In the present embodiment, the entire electroplating circulation system includes the copper dissolving device 400 and the electroplating tank 120. The copper dissolving device 400 consumes the reaction solution with Fe⁺conveyed from the main tank into the first tank body 410a. The reaction solution dissolves the pure copper, generating a Fe⁺ and a Cu⁺. An internal circulation system is provided in the copper dissolving tank 410 to maintain an ionic concentration of the solution in the copper dissolving tank 410 at a balanced level, thereby controlling the ionic concentration of the reaction solution conveyed to the electroplating tank 120 to meet a preset standard. The copper dissolving device 400 and the electroplating tank 120 are interconnected for the reciprocal convey of the solution, continuously exchanging a reaction solution containing a large amount of Fe⁺ and an electroplating solution containing a large amount of Cu⁺ and Fe⁺, thereby supplying the copper ions required for electroplating within the electroplating tank 120.

The copper dissolving device 400 has a copper particle basket 412, and pure copper is added to the copper particle basket 412. The reaction solution containing Fe⁺ reacts with the pure copper in the first tank body 410a to form an electroplating solution containing Fe⁺ and Cu⁺, and then flows from the first tank body 410a into the copper dissolving particle tank second tank body 410b. The first tank body 410a and the second tank body 410b realize internal circulation through the internal circulation mechanism. In the present embodiment, the pure copper is placed in the copper particle basket 412, then the liquid inlet of the first tank body 410a is pumped with Fe⁺ solution through the power device and pumped into the first tank 410. The pure copper of the in the first tank body 410a reacts with the Fe⁺ in the reaction solution. The Fe⁺ continuously corrodes the pure copper, thereby generating a large amount of electroplating solution containing both Fe⁺ and Cu⁺ that can be used for electroplating. The electroplating solution containing both Fe⁺ and Cu⁺ is conveyed to the electroplating tank 120 through the overflow mechanism 414 in the second tank body 410b. By using the overflow method to discharge the reaction solution, reducing a copper sludge entering the electroplating tank 120, thereby preventing contamination of the electroplating tank 120. An internal circulation system achieved by the copper dissolving tank 410 through a circulation mechanism allows for more thorough reactions, thereby reducing costs, and also balancing ion concentrations in the first tank body 410a and the second tank body 410b. The electroplating solution containing Fe⁺ and Cu⁺ from the second tank body 410b is then conveyed to the electroplating tank 120. The Cu⁺ in the electroplating solution formed in the copper dissolving tank 410 serves as the medium required for electroplating the circuit board 20. This cyclical process continues until the copper electroplating of the circuit board 20 is completed.

The technical solution of the present application involves the use of a divider plate 411 in the copper dissolving tank 410 to divide the tank into a first tank body 410a and a second tank body 410b. The divider plate 411 is provided with an overflow portion, allowing the liquid in the first tank body 410a to flow into the second tank body 410b through the overflow portion. Additionally, a conveying pipeline 413 is arranged to connect the first tank body 410a and the second tank body 410b, enabling the liquid in the second tank body 410b to flow into the first tank body 410a through the conveying pipeline 413, thereby achieving an internal circulation of the liquid between the first tank body 410a and second tank body 410b, ensuring more thorough reaction between the liquid in the copper dissolving tank 410 and the pure copper. It is sufficient to set a copper particle basket 412 in the first tank body 410a to place pure copper, without widely arranging a large number of titanium baskets, thereby improving production efficiency and reducing maintenance costs.

In one embodiment, the copper dissolving device 400 also includes a material lifting mechanism 420, the material lifting mechanism 420 is mounted at an outer side of the tank body. The lifting mechanism is configured to convey pure copper. Since the copper dissolving device 400 is relatively high and has a relatively high liquid level in the tank, some relatively large nozzles or openings are usually arranged at the top of the device to avoid leakage, and pure copper is usually added into the first tank body 410a from the top opening of the device. A material lifting mechanism 420 is provided to mechanically lift a relatively large pure copper block or pure copper ball to the opening. When additional pure copper needs to be added, the operator at a higher elevation may directly move the copper blocks on the lifting mechanism to the opening and add it, thereby facilitating the addition of the copper blocks into the copper particle basket 412.

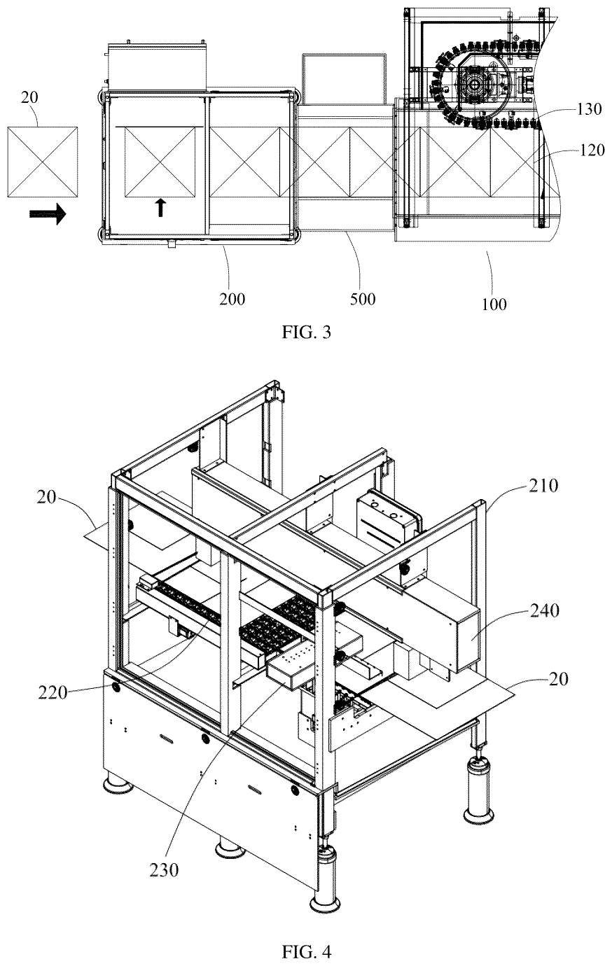

As shown in FIG. 1 and FIG. 2, the horizontal electroplating production line 10 further includes a board washing device 500 and a board drying device 600. There are a plurality of board washing devices 500, and the board washing devices 500 may be arranged at an inlet of the electroplating tank 120 of the horizontal electroplating apparatus 100 and interfaces with the circuit board feeding device 200, thereby removing impurities from the circuit board 20 in advance to remove impurities on the circuit board 20 in advance, thereby avoiding affecting the electroplating quality when the circuit board 20 enters the electroplating tank 120 for electroplating. And/or, the board washing device 500 may also be arranged at an outlet of the electroplating tank 120. After the electroplating of the circuit board 20 is electroplated, it is necessary to pickle the circuit board 20 to prevent oxidation of the circuit board 20, clean the acid solution remaining on the board surface, and remove the residual light agent on the circuit board 20. It should be noted that the number and the location of the board washing devices 500 are not specifically limited and can be arranged according to the needs of board washing.

The board drying device 600 is arranged at one side of the board washing device 500 away from an outlet of the electroplating tank 120, so as to dry the circuit board 20 after electroplating and pickling, and remove water on the circuit boards 20. At this time, the circuit board 20 needs to be cooled and slowly cooled to prevent excessive temperature difference from affecting the copper surface or even causing stress changes. It can be understood that the board drying device 600 may be connected to the board flipping device 300. If secondary electroplating is required, the cooled circuit boards 20 may be directly conveyed from the board drying device 600 to the flipping device 300. After the circuit boards 20 are flipped, it can be conveyed to the next horizontal electroplating apparatus 100 for secondary electroplating.

In one embodiment, as shown in FIG. 1, the copper dissolving device 400 and the horizontal electroplating apparatus 100 are arranged at intervals, and a passageway 30 is arranged between them for operators to pass through, so as to facilitate the inspection or operation of the apparatus on both sides. In addition, on the side of the passageway 30 away from the horizontal electroplating apparatus 100, conventional equipment such as a light additive tank, transformer, oil tank cooling tank, and pump device are provided, which will not be elaborated in detail here.

The above descriptions are only embodiments of the present application, and are not intended to limit the scope of the present application. Under the inventive concept of the present application, any equivalent structural transformations made by using the contents of the description and drawings of the present application, or direct/indirect applications in other related technical fields are included in the scope of the present application.

What is claimed is:

1. A horizontal electroplating production line, comprising:
a horizontal electroplating apparatus comprising a first frame, an electroplating tank and a horizontal electroplating conveying device arranged at the first frame, wherein two ends of the electroplating tank are respectively provided with an inlet and an outlet, and the horizontal electroplating conveying device is configured to drive a circuit board to move from the inlet into the electroplating tank towards the outlet; and
a circuit board feeding device arranged at one end of the electroplating tank close to the inlet, wherein the circuit board feeding device comprises a second frame and a feeding conveying mechanism arranged at the second frame, the feeding conveying mechanism is configured to place the circuit board horizontally and convey the circuit board along a first direction, so that the circuit board entering the electroplating tank remains horizontal and moves to the horizontal electroplating conveying device.

2. The horizontal electroplating production line according to claim 1, wherein the circuit board feeding device further comprises a first positioning mechanism and a first material pushing mechanism, the first positioning mechanism is configured to position the circuit board on the feeding conveying mechanism to a preset position, the first material pushing mechanism is configured to drive the circuit board on the feeding conveying mechanism to move in the first direction, so that adjusting a spacing between two adjacent circuit boards that are positioned by the first positioning mechanism and are arranged along the first direction.

3. The horizontal electroplating production line according to claim 2, wherein the first material pushing mechanism is configured to push the circuit board positioned by the first positioning mechanism to move in the first direction, so that a spacing between the pushed circuit board and the previous circuit board positioned by the first positioning mechanism is a preset value L, and an actual spacing between the two circuit boards is D, where L−1.5 mm≤D≤L+1.5 mm.

4. The horizontal electroplating production line according to claim 1, wherein the horizontal electroplating production line comprises a flipping device and two horizontal electroplating apparatuses, the flipping device is arranged between the two horizontal electroplating apparatuses to flip and convey the circuit board that has been electroplated in one of the horizontal electroplating apparatuses to the other horizontal electroplating apparatus, so that the horizontal electroplating conveying device of the two horizontal electroplating apparatus respectively grip opposite sides of the circuit board.

5. The horizontal electroplating production line according to claim 4, wherein the flipping device comprises a third frame, a feeding mechanism and a flipping mechanism arranged at the third frame, the feeding mechanism is configured to place the circuit board horizontally, and the flipping mechanism is configured to flip the circuit board on the feeding mechanism.

6. The horizontal electroplating production line according to claim 5, wherein the flipping mechanism comprises a driving assembly, a rotating shaft and a clamping assembly, the clamping assembly is arranged at the rotating shaft, the rotating shaft is drivingly connected to the driving assembly, the clamping assembly is provided with a slot for inserting the circuit board, and the driving assembly is configured to drive the rotating shaft to rotate, so that the clamping assembly drives the circuit board to flip.

7. The horizontal electroplating production line according to claim 6, wherein the feeding mechanism comprises a first conveying line, a second conveying line, a third conveying line and a fourth conveying line, the first conveying line and the second conveying line transport the circuit board in the first direction, the flipping mechanism is arranged between the first conveying line and the second conveying line to flip the circuit board on the first conveying line to the second conveying line, the fourth conveying line extends along a conveying direction of the first conveying line, the third conveying line is arranged along the second direction to transport the circuit board on the second conveying line to the fourth conveying line, and the first direction and the second direction forms an angle.

8. The horizontal electroplating production line according to claim 7, wherein the flipping device further comprises a second material pushing mechanism and a second positioning mechanism, the second positioning mechanism is arranged at the fourth conveying line to position the circuit board to a preset position, the second material pushing mechanism is configured to push the circuit board along the first conveying line, the second conveying line, the third conveying line and the fourth conveying line in sequence, push the circuit board positioned by the second positioning mechanism to the horizontal electroplating apparatus, and adjust the spacing between two adjacent circuit boards positioned by the second positioning mechanism and arranged along the first direction.

9. The horizontal electroplating production line according to claim 1, wherein the horizontal electroplating conveying device further comprises a clamping mechanism and an electroplating conveying mechanism, a rail is arranged at the first frame in a horizontal direction, the clamping mechanism comprises a sliding member and a clamping member connected to each other, the clamping member is arranged at the electroplating conveying mechanism to clamp the circuit board, the sliding member is slidably connected to the rail, and the electroplating conveying mechanism is configured to drive the clamping mechanism to move along the rail to convey the circuit board.

10. The horizontal electroplating production line according to claim 9, wherein the clamping member comprises:
a fixing clamp;
a movable clamp movably mounted at the fixing clamp through a connecting assembly, wherein the movable clamp is configured to cooperate with the fixing clamp to clamp the circuit board; and
a lifting support wheel arranged at a side of the movable clamp away from the fixing clamp, wherein, when the clamping mechanism moves through the electroplating conveying mechanism, the lifting support wheel ascends or descends to open or close the movable clamp and the fixing clamp.

11. The horizontal electroplating production line according to claim 10, wherein:
the horizontal electroplating conveying device further comprises a guide assembly arranged at the first frame, the guide assembly comprises a first guide member and a second guide member, the first guide member is located at a path of the clamping mechanism for loading, the second guide member is located at a path of the clamping mechanism for unloading, and both the first guide member and the second guide member have a guide slope;
on the path of the clamping mechanism for loading, when the guide slope is configured to guide the movement of the clamping mechanism and abut against the lifting support wheel, a spacing between the fixing clamp and the movable clamp is increased, in order to allow the circuit board to be clamped; and
on the path of the clamping mechanism for unloading, when the guide slope is configured to guide the movement of the clamping mechanism and abut against the lifting support wheel, the spacing between the fixing clamp and the movable clamp is increased, in order to allow the circuit board to be released.

12. The horizontal electroplating production line according to claim 9, wherein the electroplating conveying mechanism comprises:
a conveying steel belt slidably arranged at the first frame, wherein the clamping mechanism is arranged at the conveying steel belt;
a driving mechanism comprising a conveying driving wheel and a conveying driven wheel, wherein the conveying driving wheel and the conveying driven wheel are respectively arranged at two ends of the first frame, and the conveying driving wheel and the conveying driven wheel are connected through the conveying steel belt to form a closed-loop transmission to achieve continuous conveying; and
a tensioning mechanism elastically connected to the conveying steel belt and the first frame, wherein, when the conveying steel belt slides on the first frame, the tensioning mechanism undergoes elastic deformation to change a horizontal spacing between the first frame and the conveying steel belt to tension the conveying steel belt.

13. The horizontal electroplating production line according to claim 12, wherein the horizontal electroplating apparatus further comprises a cathode conductive clamp reverse stripping device comprising a deplating tank and a stripping assembly, the deplating tank is arranged at the first frame, the conveying steel belt is configured to convey the clamping mechanism into the deplating tank, so that the clamping mechanism and the stripping assembly form a conductive loop to strip an electroplating material on the clamping mechanism.

14. The horizontal electroplating production line according to claim 9, wherein:
the horizontal electroplating apparatus further comprises a conductive device comprising:
a conductive oil groove assembly provided with a conductive oil;
a cathode assembly connected with an anode of a power supply to generate a current;
a conductive slider assembly configured in the clamping mechanism, wherein the conductive slider assembly is arranged in the conductive oil groove assembly and submerged in the conductive oil, the conductive slider assembly is electrically connected to the cathode assembly to transmit the current to the horizontal electroplating fixture, so that the circuit board on the horizontal electroplating fixture is charged; and
a re-circulating mechanism comprising an oil collecting groove and a re-circulating assembly, wherein the oil collecting groove is configured to store the conductive oil, the conductive oil groove assembly is connected to the oil collecting groove through the re-circulating assembly to form a circulation path, allowing the conductive oil in the oil collecting groove to circulate with the conductive oil in the conductive oil groove assembly.

15. The horizontal electroplating production line according to claim 14, wherein the conductive device further comprises an oil supply mechanism, the re-circulating mechanism further comprises an overflow assembly, the oil supply mechanism is connected to the conductive oil groove assembly to provide the conductive oil to the conductive oil groove assembly, the overflow assembly has an overflow port, the overflow assembly is connected to the conductive oil groove assembly through the overflow port, the conductive oil groove assembly is connected to the oil collecting groove through the overflow assembly, the conductive oil groove assembly has a preset volume, when an liquid volume in the conductive oil groove assembly exceeds the preset volume, the conductive oil in the conductive oil groove assembly flows into the oil collecting groove through the overflow assembly.

16. The horizontal electroplating production line according to claim 1, wherein the horizontal electroplating apparatus further comprises an anode spray device arranged in the electroplating tank, the anode spray device comprises:
an anode mesh well plate;
an anode mesh detachably mounted at the anode mesh well plate;
a spray assembly mounted at a side of the anode mesh away from the anode mesh well plate; and
a conductive assembly, wherein the anode mesh is connected to a rectifier through the conductive assembly.

17. The horizontal electroplating production line according to claim 16, wherein at least two sets of the anode spray devices are mounted at intervals in the electroplating tank, spray sides of the two sets of the anode spray devices are arranged oppositely, and an electroplating cavity for accommodating the circuit board for electroplating is formed between any two sets of the anode spray devices arranged oppositely.

18. The horizontal electroplating production line according to claim 17, wherein the anode mesh well plate comprises:
a well plate body provided with a plurality of meshes and a plurality of first spray holes, wherein each of the meshes is arranged in a hexagonal shape, the meshes are arranged in a honeycomb array at the well plate body, a plurality of first spray holes are arranged at intervals at the well plate body, and the well plate body has a spray side facing the circuit board and spraying the circuit board; and
a guide wheel mounted at the spray side of the well plate body and configured to abut against the circuit board.

19. The horizontal electroplating production line according to claim 1, further comprising:
a copper dissolving device comprising:
a copper dissolving tank provided with a divider plate, wherein the divider plate divides the copper dissolving tank into a first tank body and a second tank body, the first tank body has a liquid inlet for a reaction solution to enter, and a copper particle basket for placing a pure copper; an upper portion of the divider plate has an overflow portion that connects the first tank body with the second tank body; the second tank body is provided with an overflow port for an outflow of the electroplating solution;
a conveying pipeline connecting the second tank body with the first tank body, so that the first tank body, the overflow portion, the second tank body and the conveying pipeline are connected to form an internal circulation loop; and
an overflow mechanism mounted at the overflow port and configured to convey the liquid in the second tank body to the electroplating tank.

20. The horizontal electroplating production line according to claim 1, further comprising:
a board washing device arranged at an entrance of the electroplating tank and located between the circuit board feeding device and the electroplating tank, and/or the board washing device arranged at an exit of the electroplating tank; and
a board drying device arranged at the exit of the electroplating tank and located at a side of the board washing device away from the electroplating tank, so as to remove water from the circuit board after electroplating and cleaning by the board washing device.
